(19) United States
(12) Patent Application Publication
(10) Pub. No.: US 2026/0202463 A1
(43) Pub. Date: Jul. 16, 2026

(54) POWER LOAD MANAGEMENT SYSTEM

(71) Applicant: JLB Companies, Salt Lake City, UT (US)

(72) Inventor: James L. Baker, Salt Lake City, UT (US)

(21) Appl. No.: 19/274,048

(22) Filed: Jul. 18, 2025

Related U.S. Application Data
(60) Provisional application No. 63/745,686, filed on Jan. 15, 2025.

(51) Int. Cl. G01R 31/28; H02J 3/001; H02J 3/14; H02J 105/50

(52) U.S. Cl. CPC G01R 31/2839; H02J 3/001; H02J 3/14; H02J 2105/51

(57) ABSTRACT

A power load management device and method of operating thereof includes a plurality of outputs configured to connect to external loads; a current sensor; and a controller. The controller is configured to perform an output test sequence comprising sequentially measuring a current of each of the outputs by the current sensor; and perform an operating loop comprising switching off the outputs when a total current exceeds a current limit.

### RELATED APPLICATIONS

This application is based on and claims the benefit of the filing date of U.S. Provisional Patent Application No. 63/745.686, filed January 15, 2025, the contents of all of which are expressly incorporated herein by reference.

### TECHNICAL FIELD

The present disclosure relates generally to a conductor for a power management system and, more particularly, to a power load management system and method of operating thereof.

### BACKGROUND

In environments such as workshops or home garages, where multiple electric charging devices are connected to a single electrical circuit, there is a significant risk of exceeding the current limit of the circuit. Electrical circuits are typically protected from overloading by circuit breakers. However, when a circuit breaker trips, the power is shut off, which can interrupt charging sessions and critical infrastructure. Frequent circuit breaker trips are inconvenient to the user. Further, if the electrical circuit or breaker is old, poorly maintained, or improperly designed, current overloading can cause damage to the electrical infrastructure, equipment failure, and safety hazards. As the number of rechargeable battery-operated devices increases in workshops and garages, the load on the electrical infrastructure increases. The amount of electrical load is often not easily discerned by the average user, and the task of managing devices can be difficult and inconvenient. There is a need for a system to manage electrical power and loads from charging devices to prevent overloading while still providing sufficient charging capacity for all of a user’s devices.

The device and method disclosed herein are directed at overcoming one or more of the problems set forth above and/or other issues in the prior art.

### SUMMARY

In one aspect of the present disclosure, a power load management device includes a plurality of outputs configured to connect to external loads; a current sensor; and a controller. The controller is configured to perform an output test sequence comprising sequentially measuring a current of each of the outputs by the current sensor; and perform an operating loop comprising switching off the outputs when a total current exceeds a current limit.

In another aspect of the present disclosure, a method for operating a power load management device includes performing an output test sequence comprising sequentially measuring a current of each of a plurality of outputs by a current sensor, the plurality of outputs configured to connect to external loads. The method further includes performing an operating loop comprising switching off the outputs when a total current exceeds a current limit.

These and other features are explained more fully in the embodiments illustrated below. It should be understood that, in general, the features of one embodiment also may be used in combination with features of another embodiment and that the embodiments are not intended to limit the scope of the disclosure.

### BRIEF DESCRIPTION OF THE DRAWINGS

FIG. 1 is an illustration of an exemplary power load management device;

FIG. 2 is a schematic illustration of the exemplary power load management device;

FIGS. 3A and 3B are flow charts illustration an exemplary method of operation for the power load management device.

### DETAILED DESCRIPTION

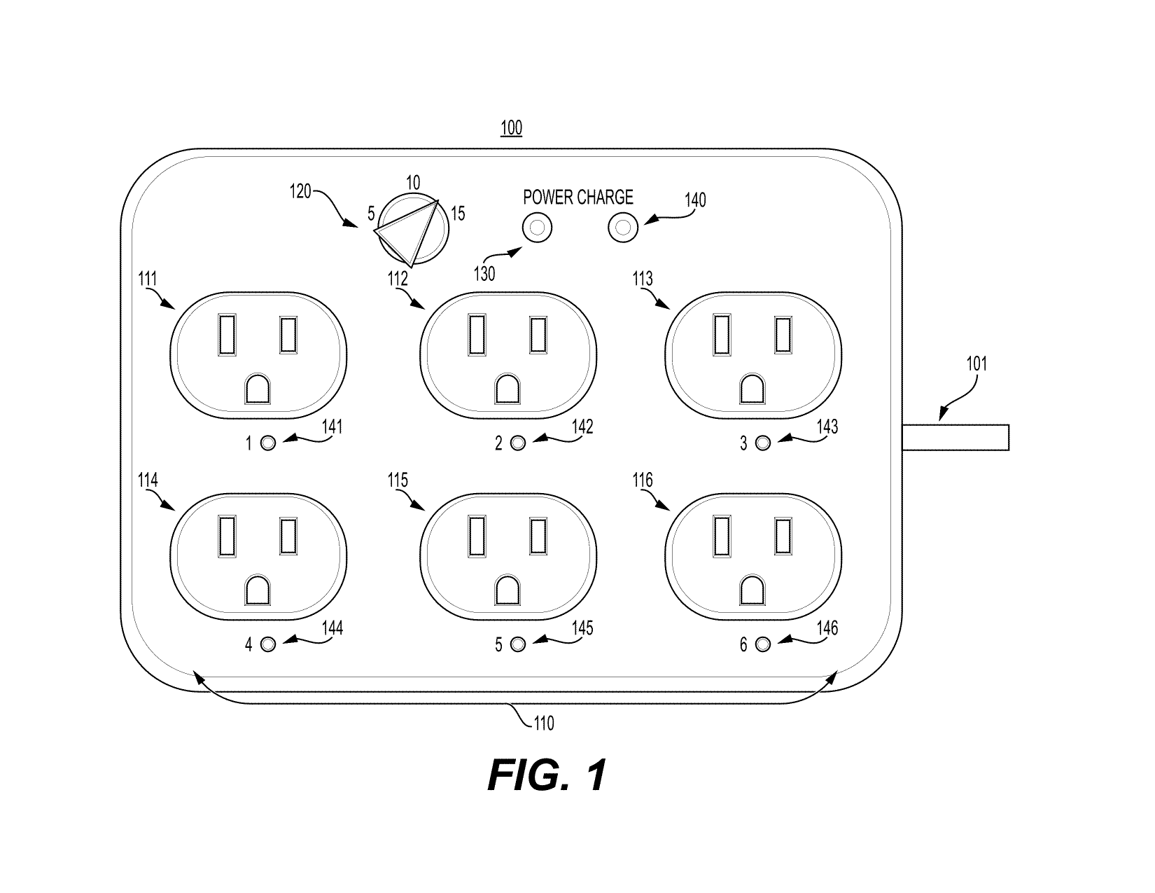

FIG. 1 illustrates an exemplary power load management device 100 for distributing power to connected loads without overloading a power supply circuit. In the exemplary embodiment, the connected loads are charging devices that charge the batteries of, for example, electric vehicles, e-bikes, electric yard appliances, power tools, and the like. Power load management device 100 manages which loads receive power in order to not exceed the current that the electrical circuit is rated for.

Power load management device 100 receives power from an input power supply via an input connector 101. For example, the input power supply may be 110V AC from a wall power supply in a household circuit connected via a breaker (not shown). In other embodiments, the input power supply may be a mains power supply of another voltage, such as 220-230V AC in a building circuit connected to the grid. In other embodiments, the input power supply may be an AC or DC power supply connected to a generator and/or battery.

Device 100 selectively distributes power to the plurality of outputs 110 (111-116) configured to be connected to external loads. Outputs 110 may be any type of electrical connector or socket appropriate for the voltage, current, and region range in which device 100 is operated. While the exemplary embodiment illustrates six outputs, in other embodiments device 100 may have any number of 2 or more outputs. Device 100 selectively distributes power to outputs 110 based on a priority order. In the exemplary embodiment, the priority order is fixed and labeled 1 through 6 (i.e., high to low priority). In other embodiments, priority may be output location-based, for example, left to right or top to bottom. In other embodiments, priority may be selected via switches located proximate to each output or via a graphical user interface (GUI). In embodiments comprising a GUI, the GUI may be displayed on a display (not shown) on device 100 or on a remote device (not shown). Selection on the GUI may be by one or more buttons, switches, or a touchscreen.

In some embodiments device 100 includes a current limit selector 120 used to select a current limit. In the exemplary embodiment current limit selector 120 is a knob, but in other embodiments current limit selector 120 may be a dial, switch, or other appropriate means for a user to select a current limit. In an alternative embodiment, current limit selector 120 may be omitted, and device 100 may have a fixed current limit. In other embodiments, the current limit is selected via a GUI. In various embodiments the current limit may include a reserve such that the actual current limit is less than the user selected current limit by a reserve amount – for example, if a user selects 15A using current limit selector 120, the actual current limit is set to 12A.

Device 100 may have a power indicator 130 and one or more charge indicators 140 (141-146) that indicate the status of power and charging, respectively. Each indicator 130 and 140-146 may be a separate light or may be combined as one light or display, which indicates power and charge status. In the exemplary embodiment illustrated in FIG. 1, device 100 has a charge indicator 140 indicating whether any device is charging and separate charge indicators 141-146 for each output 111-116. In other embodiments, device 100 may comprise charge indicator 140 or may comprise separate charge indicators 141-146.

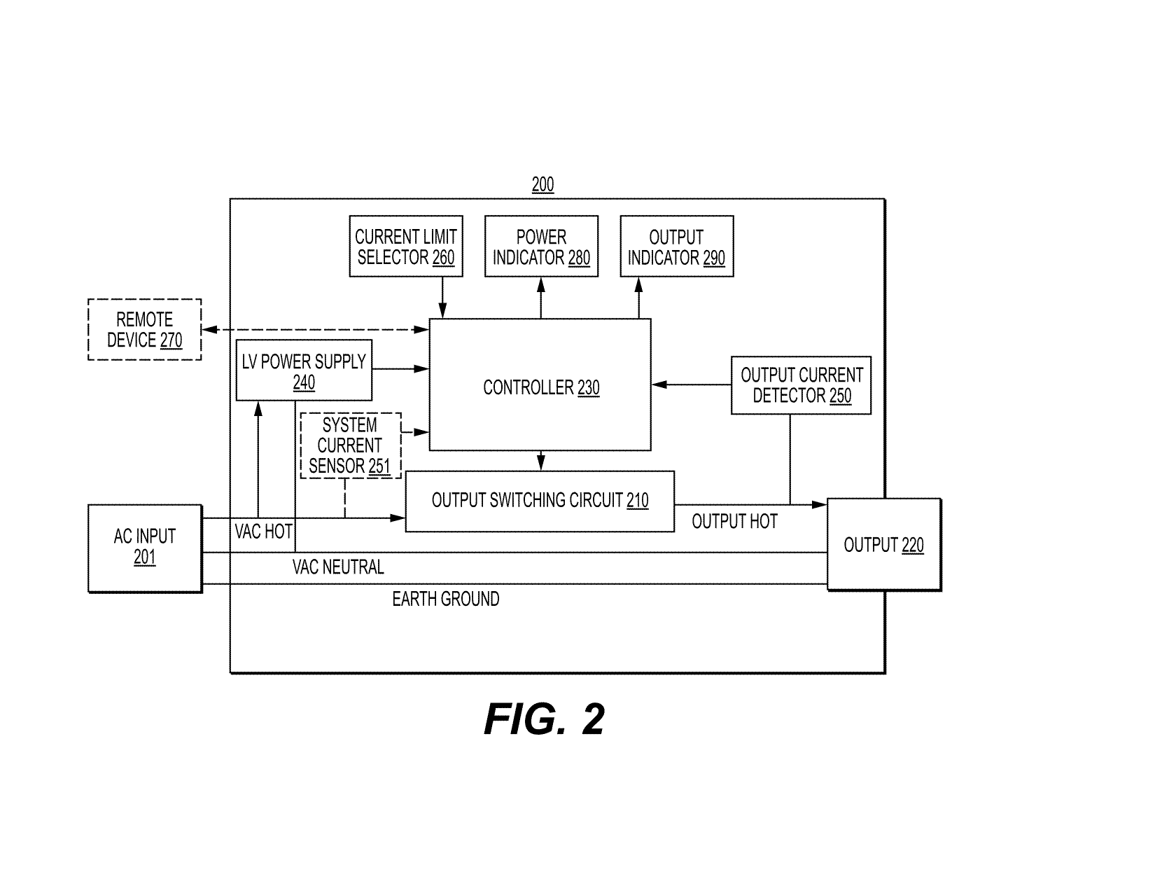

FIG. 2 illustrates a schematic diagram of an exemplary power load management device 200. Device 200 receives power from an AC input power 201 connecting device 200 to VAC Hot, VAC Neutral, and Earth Ground. Output switching circuit 210 receives power from the AC input 201. Output switching circuit 210 switches the connection to power on and off for a plurality of outputs 220. In various embodiments output switching circuit 210 comprises a mechanical or solid-state relay corresponding to each output. In some embodiments output switching circuit 210 further comprises a gate circuit including a MOSFET with resistors and diodes to ensure that the relay control voltage is set high or low to properly control the relay position. Outputs are connected to external loads, such as a battery charger. Output switching circuit 210 is controlled by controller 230. Controller 230 receives power from low-voltage (LV) power supply 240. LV power supply 240 converts the AC input power to a DC voltage appropriate to power controller 230, for example, 3.3V DC. In some embodiments, LV power supply 240 comprises an AC-DC converter and power regulator (not shown). In some embodiments, controller 230 receives a current measurement from current sensors 250 which measure the current across each respective output separately. In some embodiments, controller 230 receives a current measurement from system current sensor 251 which measures the total current across all outputs. Various embodiments may include only output current sensors 250, only system current sensor 251, or may include both output and system sensors 250,251. Controller 230 receives a current limit from current limit selector 260. Controller 230 controls output switching circuit 210 based on the current measured by current sensor 250 and the current limit selected by current limit selector 260, such that the device does not overload the input power supply.

In some embodiments, controller 230 may be a computer, a system on a chip (SOC), Application-Specific Integrated Circuit (ASIC), or Field Programmable Gate Array (FPGA). Controller 230 may include a processor, random access memory (RAM), storage, and input and output ports. The processor may be one or more microprocessors or central processing units (CPU). RAM functions as a work memory that temporarily stores data to be processed by the processor. The storage is capable of saving information that has been put therein. The storage may include a read-only memory (ROM) and rewritable non-volatile memory. As the processor executes a program stored in storage, various types of controls are carried out.

In some embodiments, controller 230 includes an interface that receives and transmits information to one or more remote devices 270. Information may be transmitted wired or wirelessly between device 200 and device 270. In some embodiments, information may be transmitted via the AC input 201 through powerline communication. Information transmitted may include current usage and current limit from device 200 and remote device 270. In an exemplary embodiment, remote device 270 is a current meter attached to a separate outlet or breaker on the electrical circuit. The current meter sends current usage information to device 200 to be included in a total current calculation so that external loads are included in the control of device 200 to prevent overloading the electrical circuit.

In another exemplary embodiment, remote device 270 is a second power load management device similar to device 200. Device 200 and second power load management device exchange their respective current limit and current usage to prevent overloading the electrical circuit. In one embodiment, the devices include the current usage of the other device in their respective calculation of total current. In another embodiment, device 200 and second power load management device adjust their respective current limit based on the current limit of the other device. For example, if both devices have a current limit set to 15A, each device will adjust its current limit down to 7.5A to split the load capacity of a 15A electrical circuit. In another embodiment, the devices adjust their respective current limit based on the current limit and current usage of the other device. For example, if both devices have a current limit set to 7.5A but one device has 0A current usage, the other device may increase its current limit to 15A. In some embodiments, both devices may include a device priority selector (not shown) to set a priority between devices. In this embodiment, the device with the higher priority powers its outputs before the device with the lower priority. Communication between the devices allows for an increased number of outputs and external loads to be managed.

In another exemplary embodiment, remote device 270 is a home automation hub. A home automation hub connects and controls multiple smart devices in a connected system. The home automation hub may transmit information such as current usage and current limit information, as described in the previous embodiments, with current meters and additional power load management devices. The home automation hub may provide a user with a GUI to display information from device 200 and allow the user to remotely control device 200 settings, such as current limit and output priority. The home automation hub may also automate this control.

Controller 230 controls the state of power indicator 280 and charge indicator 290 based on the operation of device 200. Power indicator 280 indicates whether device 100 is powered on. Charge indicator 290 indicates whether one or more outputs are powered on. Power indicator 280 and charge indicator 290 may be separate components, such as lights, or may be indications on a GUI displayed on a display (not shown). The display may be part of device 100 or a display of a remote device, such as a mobile phone.

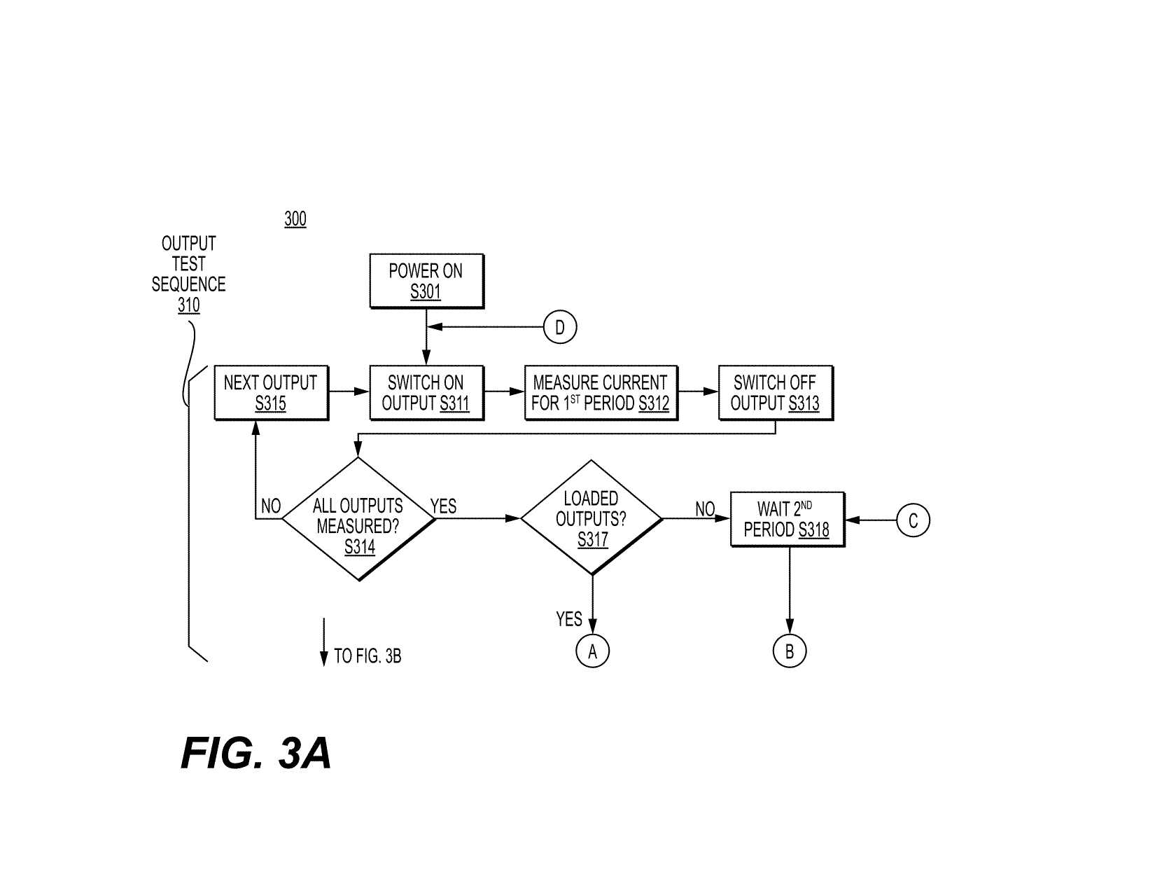

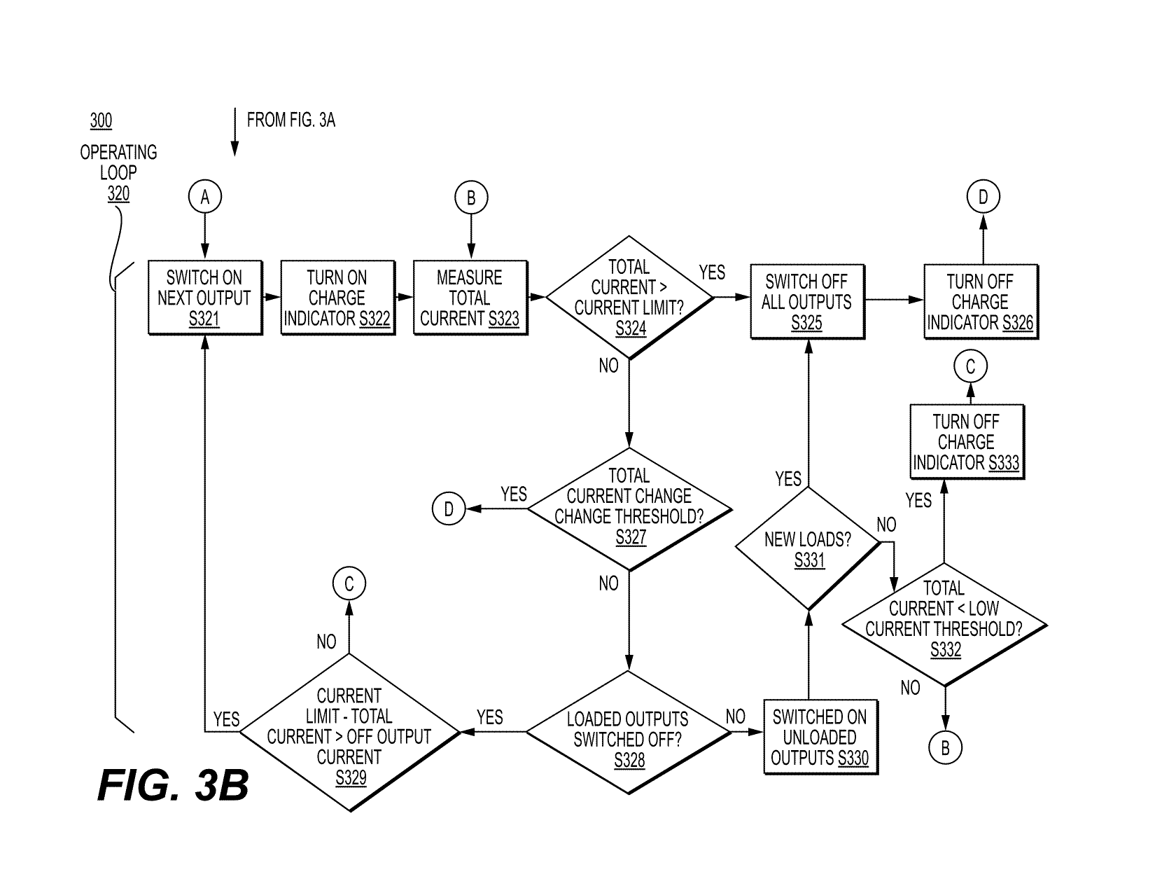

FIGS. 3A and 3B illustrate an exemplary method 300 of operating power load management device 200 executed by controller 230.

Method 300 begins when the device is powered on and controller 230 turns on power indicator 280 (Step 301). Controller 230 proceeds to perform output test sequence 310. Output test sequence 310 begins by switching on the first output in the priority sequence via output switching circuit 210 (Step 311). The current is measured by output current sensor 250 – or system current sensor 251 – for a first period, for example 120ms (Step 312). The first period allows for the connected device to power on and reach maximum current. The duration of the first period may take into account charging curves, handshake periods, and negotiation periods. In some embodiments, the first period may be extended if controller 230 determines that the current has not reached a steady state. In some embodiments the current is measured until the variation in current has decreased below a threshold for a predetermined amount of time. The maximum measured current is recorded as the output current for the respective output. In alternative embodiments the recorded output current may be the steady state current or average current. In some embodiments the measured current is filtered to account for transient current peaks.

In some embodiments an output current profile is recorded during the first period. The profile may include an amplitude of the current over time, duration to steady-state, transient behavior, multiple steady-state points, transient peaks, durations to stabilization, and percentage changs between phases. If a load is determined to match a recorded output current profile, the first period may be skipped. In some embodiments, a load is determined to match a recorded output current profile if the load has remained connected since a previous running of output test sequence 310. In some embodiments a user may select a recorded output current profile with a switch or from a GUI. In some embodiments the output current profile may be determined when a profile indicator is communicated to controller 230, such as by Radio Frequency Identification (RFID) or Near Field Communication (NFC).

When the output current has been recorded, the output is switched off (Step 313). Next, controller 230 determines whether the current of all outputs has been measured (Step 314). If it is determined that not all output currents have been measured, the method proceeds to the next output in the priority sequence (Step 315) and repeats Steps 311-313 for that output. If it is determined that all output currents have been measured, method 300 proceeds to determine if there are any loaded outputs (Step 317). If there are no loaded outputs, controller 230 waits for a second wait period (Step 318).

If there are loaded outputs, controller 230 proceeds to perform operating loop 320. Operating loop 320 begins by switching on the next output in the priority sequence (Step 321). When operating loop 320 first starts, the next output in the priority sequence will be the first loaded output. Next, charge indicator 290 is turned on (Step 322).

After turning on the charge indicator 290 in Step 322 or after the second wait period expires in Step 318, the total current of all switched-on outputs is then measured by output current sensors 250 – or system current sensor 251 (Step 323). Controller 230 then determines whether the total current measured is greater than the current limit (Step 324) set by controller 230 based on current limit selector 260 or any of the previously disclosed methods of setting the current limit. If the total current is greater than the current limit, controller 230 switches off all outputs (Step 325), turns off charge indicator 290 (Step 326), and returns to output test sequence 310. Conventional thermal-magnetic circuit breakers operate with an expected trip time that varies based on the current load. Operating loop 320 cycles within a period that is shorter than the trip time of a conventional circuit breaker for any expected current load on device 200.

If the total current is not greater than the current limit, controller 230 determines whether a percentage change in total current from a previously measured total current is greater than a change threshold, for example 25% (Step 327). If the percent change in total current is greater than the threshold, controller 230 returns to output test sequence 310. A significant decrease in total current could indicate that a load, such as a battery charger, is no longer operating. A significant increase in total could indicate that a load has changed its charging mode, such as when switching from a low current trickle charge to a high current fast charge. Such loads may be devices not appropriate for device 200 such as power tools whose current load fluctuates with usage.

If the percentage change in total current is not greater than the threshold in Step 327, controller 230 determines whether any of the loaded outputs are switched off (S328). If it is determined that a loaded output is switched off, controller 230 determines whether the difference between the current limit and the total limit is greater than the current of at least one switched off outlet measured in the output test sequence (Step 329). If the difference is greater, then it has been determined that an additional output can be switched on without exceeding the current limit. Method 300 returns to Step 321 and switches on the next output in the priority sequence. In some embodiments, the next output in the priority sequence will be switched on without determining whether the recorded output current exceeds the current difference. In other embodiments, controller 230 determines if the output current of the next output exceeds the current difference, that output is skipped and controller 230 will turn on the next output in the startup sequence that does not exceed the current difference in Step 321. If the difference is not greater (i.e. none of the switched off loaded outputs can be turned on without exceeding the current limit), the method returns to Step 318.

If all of the loaded outputs have been switched on as determined in Step 328, control 230 switches on the unloaded outputs (i.e. outputs measured to have approximately no current during output test sequence 310) (Step 330) and determines whether a new load is detected on an output based on measured current (Step 331). If a new load is detected, controller 230 switches off all outputs (Step 325), turns off charge indicator 290 (Step 326), and returns to output test sequence 310. In some embodiments, the output test sequence may be executed for all outputs. In other embodiments, the output test sequence may be executed exclusively for the outlet with the new device. If a new load is not detected, the method returns to Step 323.

If a new load is not detected, controller 230 determines if the total current is less than a low current threshold, for example, 0.1A (Step 332). If the total current is less than the low current threshold, it has been determined that the outputs are only loaded with quiescent current and are not actively operating or charging. Controller 230 turns off charge indicator 290 (Step 333) and returns to Step 318. If the total current is not less than the low current threshold indicating loaded outputs are still charging, method 300 returns to Step 323.

While the steps in method 300 are described in sequence, it will be understood that in steps may be performed simultaneously or continuously. For example, in various embodiments, the total current is continuously measures.

The disclosed power management device continuously monitors the current load of each output and adjusts the number of switched-on outputs to make use of the available current without exceeding a set current limit. The device dynamically manages the outputs to maximize output usage and device charging without damage to the electrical circuit and frequent breaker trips.

It will be apparent to those skilled in the art that various modifications and variations can be made to the device of the present disclosure. It is intended that the specification and examples be considered as exemplary only, with a true scope of the disclosure being indicated by the following claims and their equivalents.

What is claimed is:

1. A power load management device comprising:
a plurality of outputs configured to connect to external loads;
a current sensor; and
a controller configured to:
perform an output test sequence comprising sequentially measuring a current of each of the outputs by the current sensor; and
perform an operating loop comprising switching off the outputs when a total current exceeds a current limit.

2. The power load management device of claim 1, wherein the sequential measuring comprises:
switching on an output of the plurality of outputs;
measuring the current of the output for a period of time;
switching off the output; and
performing the output test sequence for a next output in the sequence until all outputs have been tested.

3. The power load management device of claim 1, wherein the period of time is based on the variation in measured current becoming less than a predetermined value.

4. The power load management device of claim 1, wherein the operating loop further comprises sequentially switching on the outputs while the total current is less than the current limit.

5. The power load management device of claim 1, wherein the operating loop further comprises switching on at least one output of the plurality of outputs based on a difference between the current limit and the total current and the output current measured in the output test sequence.

6. The power load management device of claim 1, wherein the operating loop further comprises in response to determining a change in total current exceeds a threshold, switching off the outputs.

7. The power load management device of claim 1, wherein the operating loop further comprises in response to determining that a new load has been connected to an output, switching off the outputs and performing the output test sequence.

8. The power load management device of claim 1, wherein the controller is further configured to receive an external current measurement from an external device, and wherein the total current is based on the external current measurement and a current measurement from the current sensor.

9. The power load management device of claim 1, wherein the controller is further configured to receive information from an external device, and wherein the operating look further comprises adjusting the current limit based on the information from the external device.

10. The power load management device of claim 1, further comprising an output switching circuit configured to switch the outputs, the output switching circuit comprising at least one relay.

11. A method for operating a power load management device comprising:
performing an output test sequence comprising sequentially measuring a current of each of a plurality of outputs by a current sensor, the plurality of outputs configured to connect to external loads; and
performing an operating loop comprising switching off the outputs when a total current exceeds a current limit.

12. The method of claim 11, wherein the sequential measuring comprises:
switching on a first output of the plurality of outputs;
measuring the current of the first output for a period of time;
switching off the first output; and
performing the output sequence for the next output in the sequence until all outputs have been tested.

13. The method of claim 11, wherein the period of time is based on the variation in measured current becoming less than a predetermined value.

14. The method of claim 11, wherein the operating loop further comprises sequentially switching on outputs while the total current is less than the current limit.

15. The method of claim 11, wherein the operating loop further comprises switching on at least one output of the plurality of outputs based on a difference between the current limit and the total current and the output current measured in the output test sequence.

16. The method of claim 11, wherein the operating loop further comprises in response to determining a change in total current exceeds a threshold, switching off the outputs.

17. The method of claim 11, wherein the operating loop further comprises in response to determining that a new load has been connected to an output, switching off the outputs and performing the output test sequence.

18. The method of claim 11, further comprising receiving an external current measurement from an external device, and wherein the total current is based on the external current measurement and a current measurement from the current sensor.

19. The method of claim 11, further comprising receiving information from an external device, and wherein the operating look further comprises adjusting the current limit based on the information from the external device.

20. The method of claim 11, wherein the switching of outputs is performed by an output switching circuit, the output switching circuit comprising at least one relay.
